(19) United States
(12) Patent Application Publication
(10) Pub. No.: US 2026/0187295 A1
(43) Pub. Date: Jul. 2, 2026

(54) METHOD AND SYSTEM FOR UPDATING GEOLOGICAL PROCESS MODELS USING MULTISCALE SEARCH TEMPLATES AND WELL DATA

(71) Applicant: SAUDI ARABIAN OIL COMPANY, Dhahran (SA)

(72) Inventors: Yupeng Li, Beijing (CN); Lin Ying Hu, Beijing (CN)

(73) Assignees: ARAMCO FAR EAST (BEIJING) BUSINESS SERVICES CO., LTD, Beijing (CN); SAUDI ARABIAN OIL COMPANY, Dhahran (SA)

(21) Appl. No.: 18/727,738

(22) PCT Filed: Oct. 26, 2023
(86) PCT No.: PCT/CN2023/126821

§ 371 Date: Jul. 10, 2024

(51) Int. Cl. G06F 30/13

(52) U.S. Cl. CPC G06F 30/13

(57) ABSTRACT

A method may include obtaining well data regarding a geological region of interest. The method may further include obtaining a geological process model for the geological region of interest. The method may further include determining a simulation region of the geological process model based on a template size and a simulation grid. The method may further include determining a simulation path through the simulation region. The method may further include determining a geological event associated with a predetermined geological facies based on the well data. The method may further include determining a replicate event based on the geological event, a similarity analysis, and using the simulation path. The method may further include assigning the predetermined geological facies to a cell location of the replicate event in the simulation region. The method may further include updating the geological process model to produce an updated geological process model.

### BACKGROUND

Geological process modeling may include forward modeling stratigraphic and sedimentary processes to accurately describe various geological regions. For example, forward stratigraphic modelling may be used to predict reservoir potential in sedimentary basins, such as continental, marine, siliciclastic, and carbonate systems. Likewise, stratigraphic modeling may be used to determine various uncertainties in depositional settings, such as sedimentation rate, water discharges, and sea level fluctuations. Through geological process modeling, stratigraphic models may be used to simulate expected sediment geometries and predict lithology distributions in the subsurface.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

In general, in one aspect, embodiments relate to a method that includes obtaining well data regarding a geological region of interest. The method further includes obtaining a geological process model for the geological region of interest. The method further includes determining, by a computer processor, a simulation region of the geological process model based on a template size and a simulation grid. The method further includes determining, by the computer processor, a simulation path through the simulation region. The method further includes determining, by the computer processor, a geological event associated with a predetermined geological facies based on the well data. The method further includes determining, by the computer processor, a replicate event based on the geological event, a similarity analysis, and using the simulation path. The method further includes assigning, by the computer processor, the predetermined geological facies to a cell location of the replicate event in the simulation region in response to determining that the replicate event satisfies a predetermined criterion. The method further includes updating, by the computer processor, the geological process model to produce an updated geological process model, where the updated geological process model includes the predetermined geological facies in the cell location of the updated geological process model.

In general, in one aspect, embodiments relate to a system that includes a drilling system includes various sensors and a drill string that includes a drill bit. The drilling system is coupled to a wellbore. The system further includes a reservoir simulator coupled to the drilling system. The reservoir simulator includes a computer processor. The reservoir simulator obtains well data regarding a geological region of interest. The reservoir simulator obtains a geological process model for the geological region of interest. The reservoir simulator determines a simulation region of the geological process model based on a template size and a simulation grid. The reservoir simulator determines a simulation path through the simulation region. The reservoir simulator determines a geological event associated with a predetermined geological facies based on the well data. The reservoir simulator determines a replicate event based on the geological event, a similarity analysis, and using the simulation path. The reservoir simulator assigns the predetermined geological facies to a cell location of the replicate event in the simulation region in response to determining that the replicate event satisfies a predetermined criterion. The reservoir simulator updates the geological process model to produce an updated geological process model, where the updated geological process model includes the predetermined geological facies in the cell location of the updated geological process model. The drilling system performs a drilling operation for a well path based on the updated geological process model.

In some embodiments, a training image is obtained based on a geological process model. A simulation grid may be determined based on the training image. The simulation region may correspond to a portion of the simulation grid that matches a template size. In some embodiments, a geological event is determined at a first cell position in a geological process model. A replicate event may be determined at a second cell position in a simulation region along a simulation path. A comparison between the geological event and the replicate event using a similarity metric. A determination may be made whether the geological event and the replicate event satisfy a similarity threshold based on the comparison. The replicate event may be determined to correspond to the geological event in response to the comparison satisfying the similarity threshold.

In some embodiments, a template size is determined for a simulation path. A first set of replicate events in a simulation region may be determined using the template size. The template size may be adjusted to produce an adjusted template size. The adjusted template size may be smaller than the previous template size. A second set of of replicate events in the simulation region may be determined using the adjusted template size.

In some embodiments, a predetermined geological facies is selected from a group consisting of a floodplain mud, a fluvial channel sand, an alluvial siltstone, and an alluvial mud. In some embodiments, a presence of hydrocarbons is determined in a geological region of interest using an updated geological process model. In some embodiments, a well operation is adjusted at a predetermined well based on an updated geological process model and using a control system coupled to a reservoir simulator. The updated geological process model may be updated by the reservoir simulator. In some embodiments, a portion of the well data is based on various elemental logs for one or more wellbores. The elemental logs may be determined using various cuttings and an X-ray fluorescence (XRF) spectrometer. In some embodiments, a command is transmitted to a control system based on an updated geological process model. The control system may be coupled to a wellhead assembly. The command may adjust one or more production parameters of the wellhead assembly.

In some embodiments, a coring system includes a coring tool. One or more core samples may be acquired from a wellbore using the coring tool. a portion of well data may be based on core sample data using the one or more core samples. In some embodiments, a logging system includes a logging tool. One or more well logs may be acquired from a wellbore using the logging tool. A portion of well data is based on well log data using the one or more well logs.

In light of the structure and functions described above, embodiments of the invention may include respective means adapted to carry out various steps and functions defined above in accordance with one or more aspects and any one of the embodiments of one or more aspect described herein.

Other aspects and advantages of the claimed subject matter will be apparent from the following description and the appended claims.

### BRIEF DESCRIPTION OF DRAWINGS

Specific embodiments of the disclosed technology will now be described in detail with reference to the accompanying figures. Like elements in the various figures are denoted by like reference numerals for consistency.

FIGS. 1, 2A, 2B, and 3 show systems in accordance with one or more embodiments.

FIG. 4 shows a flowchart in accordance with one or more embodiments.

FIGS. 5A, 5B, 5C, 5D, 5E, 5F, 5G, 5H, 6A, 6B, and 6C show examples in accordance with one or more embodiments.

FIG. 7 shows a computer system in accordance with one or more embodiments.

### DETAILED DESCRIPTION

In the following detailed description of embodiments of the disclosure, numerous specific details are set forth in order to provide a more thorough understanding of the disclosure. However, it will be apparent to one of ordinary skill in the art that the disclosure may be practiced without these specific details. In other instances, well-known features have not been described in detail to avoid unnecessarily complicating the description.

Throughout the application, ordinal numbers (e.g., first, second, third, etc.) may be used as an adjective for an element (i.e., any noun in the application). The use of ordinal numbers is not to imply or create any particular ordering of the elements nor to limit any element to being only a single element unless expressly disclosed, such as using the terms “before”, “after”, “single”, and other such terminology. Rather, the use of ordinal numbers is to distinguish between the elements. By way of an example, a first element is distinct from a second element, and the first element may encompass more than one element and succeed (or precede) the second element in an ordering of elements.

In general, embodiments of the disclosure include systems and methods for updating a geological process model using one or more conditioning techniques based on acquired well data. More specifically, process-based geological modeling or forward stratigraphic modeling may be used to mimic various physical laws that govern depositional processes, diagenetic processes, and other geological processes. In some embodiments, for example, a statistical pattern recognition process is applied to various cells within a geological process model using an adjustable search template. In particular, different portions of the model may be used as training images for this statistical pattern recognition. Additionally, a selected search template may be used to sample and analyze cells for similarity to different geological events. If cells around a cell of interest (e.g., the center cell in a simulation region) sufficiently matches a geological event in another portion of the model, the conditioning technique may identify the arrangement of cells as being the same geological facies as the respective geological event. Thus, the conditioning technique may traverse all cells without hard acquired well data within an initial geological process model to assign or update the associated geological facies of the respective cells.

In some embodiments, a selected search template is used by a reservoir simulator to determine which neighboring cells to use for the data analysis. For example, the search template may define an arrangement of cells in a simulation region that is a subset of a training image. This simulation region may be used with pattern recognition for analyzing geological processes based on hard well data for the region and previously simulated data. Furthermore, a selected search template may be used to determine one or more simulations paths for traversing a particular simulation region as well as remaining portions of a geological process model. Using different template sizes to search for replicated geological events may better capture geological features in some embodiments. For instance, at the early stage of a conditioning process, a smaller number of simulated cells may be available for identifying geological processes. Thus, a larger search template may increase the change of identifying geological facies for a particular cell of interest using a greater number of neighboring cells. On the other hand, once a simulation grid is mostly traversed near the end of a conditioning process, a smaller search template may provide an increased likelihood of identifying replicate events.

Furthermore, some embodiments implement a multiscale regionalized direct sampling method that is distinct from various prior art techniques. For illustration, some prior art methods may have a stationary set of cells for use in identifying different geological facies in a model. In contrast, some embodiments use a dynamic set of cells, where the selection of neighboring cells around a cell of interest changes based on the location of the cell of interest as well as the size of the search template. Likewise, some embodiments also differ from the multi-grid conditioning techniques where cells of interest are relocated to adapt grid changes. For example, some multi-grid conditioning techniques use a relatively small search template where the template size remains unchanged throughout the conditioning process, but multiple grid systems are used at different scales to model heterogeneity. These multi-grad conditioning techniques may require additional computing resources in order to relocate simulated and acquired well data to each new grid system. Accordingly, some embodiments improve geological process modeling using an adjustable search template that provides more accurate data conditioning between simulated data and acquired well data.

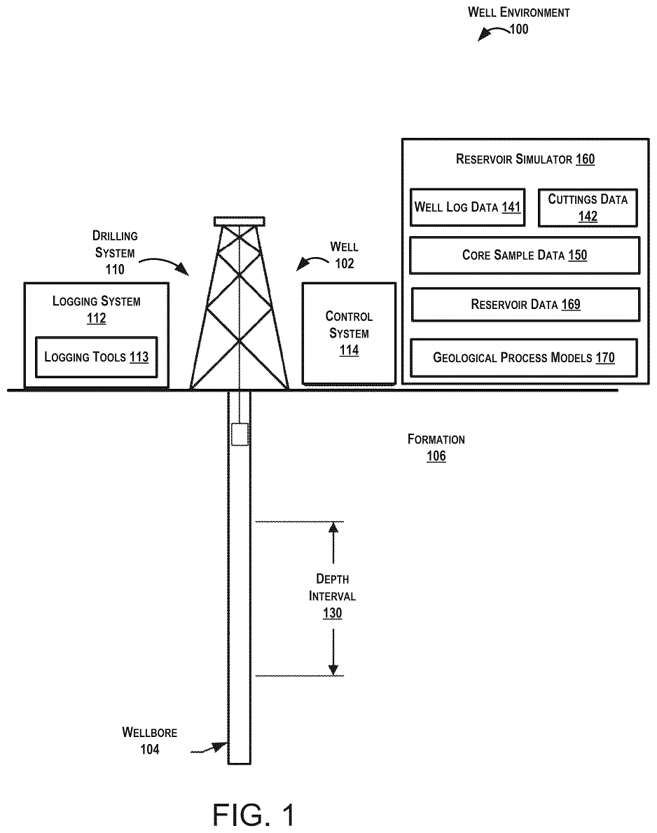

Turning to FIG. 1, FIG. 1 shows a schematic diagram in accordance with one or more embodiments. As shown, FIG. 1 illustrates a well environment (100) that may include a well (102) having a wellbore (104) extending into a formation (106). The wellbore (104) may include a bored hole that extends from the surface into a target zone of the formation (106), such as a reservoir. The formation (106) may include various formation characteristics of interest, such as formation porosity, formation permeability, resistivity, density, water saturation, and the like. Porosity may indicate how much space exists in a particular rock within an area of interest in the formation (106), where oil, gas, and/or water may be trapped. Permeability may indicate the ability of liquids and gases to flow through the rock within the area of interest. Resistivity may indicate how strongly rock and/or fluid within the formation (106) opposes the flow of electrical current. For example, resistivity may be indicative of the porosity of the formation (106) and the presence of hydrocarbons. More specifically, resistivity may be relatively low for a formation that has high porosity and a large amount of water, and resistivity may be relatively high for a formation that has low porosity or includes a large amount of hydrocarbons. Effective porosity may refer to that portion of the total void space of a porous material that is capable of transmitting a fluid. Effective permeability may refer to a state effective permeability as a function of a rock's absolute permeability. Water saturation may indicate the fraction of water in a given pore space.

Keeping with FIG. 1, the well environment (100) may include a reservoir simulator (160) and various well systems, such as a drilling system (110), a logging system (112), a control system (114), and a well completion system (not shown). The drilling system (110) may include a drill string, drill bit, a mud circulation system and/or the like for use in boring the wellbore (104) into the formation (106). The control system (114) may include hardware and/or software for managing drilling operations and/or maintenance operations. For example, the control system (114) may include one or more programmable logic controllers (PLCs) that include hardware and/or software with functionality to control one or more processes performed by the drilling system (110). Specifically, a programmable logic controller may control valve states, fluid levels, pipe pressures, warning alarms, and/or pressure releases throughout a drilling rig. In particular, a programmable logic controller may be a ruggedized computer system with functionality to withstand vibrations, extreme temperatures, wet conditions, and/or dusty conditions, for example, around a drilling rig. Without loss of generality, the term “control system” may refer to a drilling operation control system that is used to operate and control the equipment, a data acquisition and monitoring system that is used to acquire equipment data and to monitor one or more well operations, or a well interpretation software system that is used to analyze and understand well events, such as drilling progress. A logging system may be similar to a control system with a specific focus on managing one or more logging tools.

Turning to the reservoir simulator (160), a reservoir simulator (160) may include hardware and/or software with functionality for storing and analyzing well log data (141), such as borehole image data, cutting data (142) from drilling cuttings acquired from drilling fluid circulating in a wellbore, core sample data (150), seismic data, reservoir data (169), such as porosity data and permeability data, and/or other types of data to generate and/or update one or more geological process models (170), such as models that describe sedimentary or diagenetic processes. Borehole image data may be based on electrical and/or acoustic logging techniques, for example. Geological process models may include geochemical or geomechanical models that describe structural relationships within a particular geological region. Cutting data may describe an analysis or rock typing performed on drill cuttings from a drilling operation, such as using visual methods of describing rock and pore characteristics. These different data types may be acquired during exploration, reservoir characterization, hydraulic fracturing, and production operations.

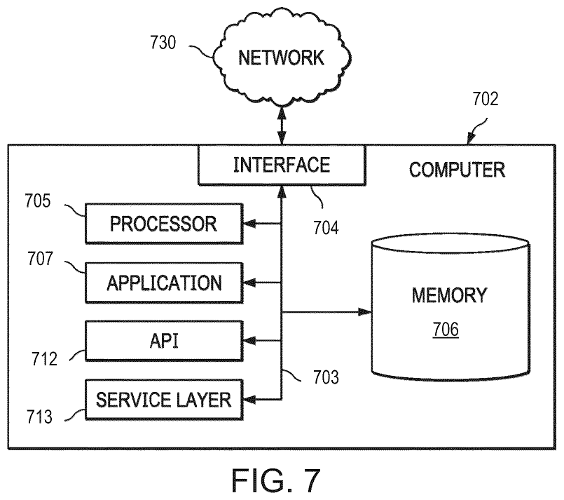

While the reservoir simulator (160) is shown at a well site, in some embodiments, the reservoir simulator (160) may be remote from a well site. In some embodiments, the reservoir simulator (160) is implemented as part of a software platform for the control system (114). The software platform may obtain data acquired by the drilling system (110) and logging system (112) as inputs, which may include multiple data types from multiple sources. The software platform may aggregate the data from these systems (110, 112) in real time for rapid analysis. In some embodiments, the control system (114), the logging system (112), the reservoir simulator (160), and/or a user device coupled to one of these systems may include a computer system that is similar to the computer system (702) described below with regard to FIG. 7 and the accompanying description.

The logging system (112) may include one or more logging tools (113) for use in generating well logs of the formation (106). For example, a logging tool may be lowered into the wellbore (104) to acquire measurements as the tool traverses a depth interval (130) (e.g., a targeted reservoir section) of the wellbore (104). The plot of the logging measurements versus depth may be referred to as a “log” or “well log”. Well log data (141) may provide depth measurements of the wellbore (104) that describe such reservoir characteristics as formation porosity, formation permeability, resistivity, water saturation, and the like. The resulting logging measurements may be stored and/or processed, for example, by the control system (114), to generate corresponding well logs for the well (102). A well log may include, for example, a plot of a logging response time versus true vertical depth (TVD) across the depth interval (130) of the wellbore (104).

Turning to examples of logging techniques, multiple types of logging techniques are available for determining various reservoir characteristics. In some embodiments, gamma ray logging is used to measure naturally occurring gamma radiation to characterize rock or sediment regions within a wellbore. In particular, different types of rock may emit different amounts and different spectra of natural gamma radiation. For example, gamma ray logs may distinguish between shales and sandstones/carbonate rocks because radioactive potassium may be common to shales. Likewise, the cation exchange capacity of clay within shales may also result in higher absorption of uranium and thorium further increasing the amount of gamma radiation produced by shales.

Turning to nuclear magnetic resonance (NMR) logging, an NMR logging tool may measure the induced magnetic moment of hydrogen nuclei (i.e., protons) contained within the fluid-filled pore space of porous media (e.g., reservoir rocks). Thus, NMR logs may measure the magnetic response of fluids present in the pore spaces of the reservoir rocks. In so doing, NMR logs may measure both porosity and permeability, as well as the types of fluids present in the pore spaces. Thus, NMR logging may be a subcategory of electromagnetic logging that responds to the presence of hydrogen protons rather than a rock matrix. Because hydrogen protons may occur primarily in pore fluids, NMR logging may directly or indirectly measure the volume, composition, viscosity, and distribution of pore fluids.

Turning to spontaneous potential (SP) logging, SP logging may determine the permeabilities of rocks in the formation (106) by measuring the amount of electrical current generated between drilling fluid produced by the drilling system (110) and formation water that is held in pore spaces of the reservoir rock. Porous sandstones with high permeabilities may generate more electricity than impermeable shales. Thus, SP logs may be used to identify sandstones from shales.

Another type of electrical logging technique is resistivity logging. Resistivity logging may measure the electrical resistivity of rock or sediment in and around the wellbore (104). In particular, resistivity measurements may determine what types of fluids are present in the formation (106) by measuring how effective these rocks are at conducting electricity. Because fresh water and oil are poor conductors of electricity, they have high resistivities. As such, resistivity measurements obtained via such logging can be used to determine corresponding reservoir water saturation (S_{w}).

Another electrical logging technique is dielectric logging. For example, dielectric permittivity may be defined as a physical quantity that describes the propagation of an electromagnetic field through a dielectric medium. As such, dielectric permittivity may describe a physical medium's ability to polarize in response to an electromagnetic field, and thus reduce the total electric field inside the physical medium. In a portion of reservoir rock, water may have a large dielectric permittivity that is higher than any associated rock or hydrocarbon fluids within the portion. In particular, water permittivity may depend on a frequency of an electromagnetic wave, water pressure, water temperature, and salinity of the reservoir rock mixture. Likewise, a multi-frequency dielectric logging tool may determine a value of the water-filled porosity in the reservoir rock.

Keeping with dielectric logging, a dielectric logging tool may determine a dielectric constant (i.e., relative-permittivity) measurement. For example, the dielectric logging tool may include an antenna that detects relative dielectric constants between different fluids at a fluid interface. As such, a dielectric logging tool may generate a dielectric log of the high-frequency dielectric properties of a formation. In particular, a dielectric log may include two curves, where one curve may describe the relative dielectric permittivity of the analyzed rock and the other curve may describe the resistivity of the analyzed rock. Relative dielectric permittivity may be used to distinguish hydrocarbons from water of differing salinities. However, the effect of salinity may be more important than the salinity effect with a high-frequency dielectric log (also called an “electromagnetic propagation log”).

Turning to sonic logging or acoustic logging, the logging system (112) may measure the speed that acoustic waves travel through rocks in the formation (106) to determine porosity in the formation (106). This type of logging may generate borehole compensated (BHC) logs, which are also called sonic logs. In general, sound waves may travel faster through high-density shales than through lower-density sandstones. Other types of logging include density logging and neutron logging. Density logging may determine porosity measurements by directly measuring the density of the rocks in the formation (106). Furthermore, neutron logging may determine porosity measurements by assuming that the reservoir pore spaces within the formation (106) are filled with either water or oil and then measuring the amount of hydrogen atoms (i.e., neutrons) in the pores.

Turning to coring, reservoir characteristics may be determined using core sample data (e.g., core sample data (150)) acquired from a well site. For example, certain reservoir characteristics can be determined via coring (e.g., physical extraction of rock specimens) to produce core specimens and/or logging operations (e.g., wireline logging, logging-while-drilling (LWD) and measurement-while-drilling (MWD)). Coring operations may include physically extracting a rock specimen from a region of interest within the wellbore (104) for detailed laboratory analysis. For example, when drilling an oil or gas well, a coring bit may cut core plugs (or “cores” or “core specimens”) from the formation (106) and bring the core plugs to the surface, and these core specimens may be analyzed at the surface (e.g., in a lab) to determine various characteristics of the formation (106) at the location where the specimen was obtained.

Turning to various coring technique examples, conventional coring may include collecting a cylindrical specimen of rock from the wellbore (104) using a core bit, a core barrel, and a core catcher. The core bit may have a hole in its center that allows the core bit to drill around a central cylinder of rock. Subsequently, the resulting core specimen may be acquired by the core bit and disposed inside the core barrel. More specifically, the core barrel may include a special storage chamber within a coring tool for holding the core specimen. Furthermore, the core catcher may provide a grip to the bottom of a core and, as tension is applied to the drill string, the rock under the core breaks away from the undrilled formation below coring tool. Thus, the core catcher may retain the core specimen to avoid the core specimen falling through the bottom of the drill string. In some embodiments, a micro computed tomography (micro-CT) scan is performed on a core sample. Several types of micro-CT scanning may be used, such as a desktop micro-CT scanner that uses an X-ray generation tube, and a synchrotron X-ray micro-tomography. In particular, a micro-CT scanner may use various X-rays to penetrate from different viewpoints in a core sample to produce an attenuated projection profile that is used for later reconstruction using a filtered back projection algorithm.

In some embodiments, cutting samples are acquired and analyzed from one or more drilling operations to determine various geological properties of one or more formations. In particular, cuttings may be initially cleaned in liquid detergent to remove drilling additives and before being dried on a ‘hotplate’. Dried cutting samples may be passed through one or more sieves to remove fragments of various sizes. Likewise, a magnet may be placed over a sieved cutting sample to remove any metallic fragments acquired during a drilling operation. After selecting various desired samples from the sieving and other preparation processes, selected samples may be ground into a fine powder for analysis using X-ray fluorescence (XRF) spectrometry processing and/or and inductively coupled plasma (ICP) spectrometry processing.

Turning to XRF spectrometry, XRF spectrometry may be performed using an XRF spectrometer. For example, an XRF spectrometer may be an x-ray instrument that is used for chemical analyses of rocks, minerals, sediments and fluids. In particular, the XRF spectrometer may use various wavelength-dispersive spectroscopic principles similar to the principles used by an electron probe microanalysis (EPMA). While an XRF spectrometer cannot generally perform chemical analyses at small spot sizes (e.g., 2-5 microns), an XRF spectrometer may be used for bulk analyses of larger samples of geological materials, such as for major chemical components and trace chemical elements in rocks, minerals, and sediment. Moreover, the analysis of major and trace elements in geological materials by X-ray fluorescence may be performed by analyzing the behavior of atoms interacting with radiation (e.g., high-energy short wavelength radiation, such as X-rays). When cutting samples or core samples are excited with X-rays, these geological samples may become ionized. If the transmitted radiation energy is sufficient to dislodge an inner electron, the atom may become unstable and an outer electron may replace the missing inner electron. Subsequently, energy may be released due to the decreased binding energy of the inner electron orbital compared with an outer one. The emitted radiation (i.e., fluorescent radiation) may thus be of lower energy than the primary incident X-rays. Because the energy of the emitted photon is characteristic of a transition between specific electron orbitals in a particular element, the resulting fluorescent X-rays may be used to determine elemental compositions in a cutting sample or core sample.

Turning to ICP spectrometry, ICP spectrometry may include inductively coupled plasma-optical emission spectrometry (ICP-OES) or inductively coupled plasma-mass spectrometry (ICP-MS). For example, ICP-OES and ICP-MS may be used to perform geochemical analyses to determine the presence of major elements (e.g., aluminum (Al), silicon (Si), titanium (Ti), iron (Fe), manganese (Mn), magnesium (Mg), calcium (Ca), sodium (Na), potassium (K), and phosphorus (P)), trace elements (e.g., barium (Ba), beryllium (Be), cobalt (Co), chromium (Cr), cesium (Cs), copper (Cu) etc.), and rare earth elements (REEs). Furthermore, ICP-OES processes may provide an analytical technique for determining the quantities of certain elements that are included in a core sample or a cutting sample. an ICP-OES process may use the principle that atoms and ions can absorb energy to move electrons from the ground state to an excited state, where the energy source is heat from an argon plasma that operates at 10,000 Kelvin. Thus, ICP-OES process may rely on various excited atoms releasing light at specific wavelengths to determine elemental compositions. Moreover, the amount of light released at each wavelength may be proportional to the number of atoms or ions making the transition.

Turning to ICP-MS processes, ICP-MS may include a type of mass spectrometry that uses an inductively coupled plasma to ionize a particular sample. For example, an ICP-MS process may atomize the sample to produce atomic and small polyatomic ions, that may be detected. As such, ICP-MS may be used for detecting metals and several non-metals in liquid samples at very low concentrations. Thus, an ICP-MS process may determine different isotopes of the same element, which may be used for isotopic labeling. Additionally, inductively coupled plasma processes may have two operation modes, i.e., a capacitive (E) mode with low plasma density and an inductive (H) mode with high plasma density.

Turning to chemical weathering, weathering index data may describe one or more chemical indexes of alteration (CIA) that may be used to assess the degree of chemical weathering in a geological region, e.g., to characterize the corresponding palaeoclimate. In particular, weathering index data may determine from the major element geochemistry of bulk sediment samples (e.g., core samples and cutting samples). For example, weathering index data may quantify the extent that various sediments have experienced chemical weathering. Likewise, weathering index data may provide an indication of the relative abundances of “unweathered” material and chemical weathering products. In other words, “unweathered” materials may include feldspars (e.g., which are common and may contain relatively mobile Ca, Na, and K constituent elements), while chemical weathered materials may include Al-rich clays. For illustration, a CIA of a sediment may increase as the extent of chemical weathering increases (e.g., from values of approximately 50 for “unweathered” feldspar-rich rocks to values near 100 for highly weathered, kaolinite- or gibbsite-rich sediments). In particular, CIA values for “average” shales may range from 70 to 75, such as those dominated by illite, where the CIA value for a sediment may also increase as grain size decreases. Likewise, trace element abundances may also serve as indicators of sediment provenance because trace elements are also relatively immobile during weathering.

Furthermore, some geological process models may describe various deep seated clastic reservoirs. For example, a clastic reservoir may be tighter because of diagenesis that results in the breakdown of minerals to produce clays. These clays may precipitate in pore throats, resulting in clogging that destroys permeability of rocks. As such, identification of zones of low clay precipitation may be used to place wells, select testing intervals, and determine stimulation operations to enhance permeability to increase hydrocarbon production in a reservoir. Furthermore, clastic reservoirs may include sandstone reservoirs that have extensive hydrocarbon accumulation, while being characterized by low porosity and variable permeability due to compaction and various diagenetic processes through the geological time. In particular, diagenesis may refer to the physical and chemical processes occurring from the start of deposition continuing through compaction, cementation, and dissolution which impact reservoir quality heterogeneities. Reservoir petrography and geochemical analysis on deep seated tight sandstone formations have shown the reservoir includes quartz and feldspar as grains, cements that include quartz overgrowth, and clay minerals such as illite and kaolinite.

In some embodiments, a geological process model is based on forward stratigraphic modeling that numerically simulates the physical laws which govern fluid flow and a variety of depositional processes. These geological processes include the sediment erosion, transport and deposition, as well as formation compaction, porosity reduction, fold deformation, diagenesis and fluid maturation, etc. Thus, various input parameters for geological process modeling may include paleo-topography, sediment input rates, transport rates, sea level changes, and tectonic subsidence history during the geological time for those depositional processes. A resulting geological process model after simulation may include stratigraphic spatial architectures, such as the thickness of each formation and the geological facies within each formation. The petrophysical property of the simulated area, such as porosity, permeability or other rock properties can also be represented in the geological process model. Furthermore, the input parameters for geological processing modelling may be derived from well data and other data, such as seismic surveys and other measurement collected in a geological region of interest.

Keeping with FIG. 1, geosteering may be used to position the drill bit or drill string of the drilling system (110) relative to a boundary between different subsurface layers (e.g., overlying, underlying, and lateral layers of a pay zone) during drilling operations. In particular, one or more geological model may be used by the drilling system (110) for steering the drill bit in the direction of desired hydrocarbon concentrations. In some embodiments, a well path of a wellbore (104) may be updated by the control system (114) using a geological model. In some embodiments, a geological model of the subsurface is based on a geological process model. Additionally, a control system (114) may communicate geosteering commands to the drilling system (110) based on well log data updates or predicted hydrocarbon data that are further adjusted by the reservoir simulator (160) using a geological model. As such, the control system (114) may generate one or more control signals for drilling equipment (or a logging system may generate for logging equipment) based on an updated well path design and/or an updated geological model. As such, a geosteering system may use various sensors located inside or adjacent to the drill string to determine different rock formations within a well path. In some geosteering systems, drilling tools may use resistivity or acoustic measurements to guide the drill bit during horizontal or lateral drilling.

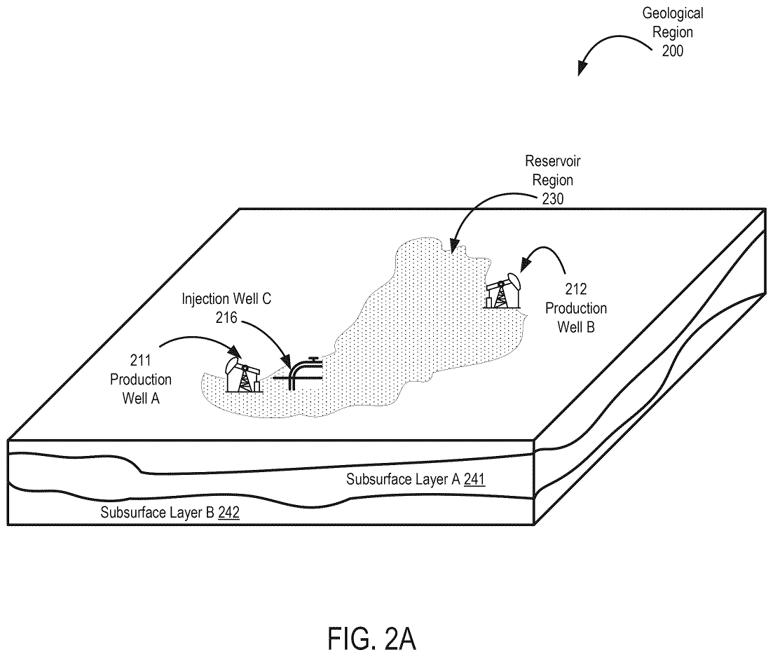

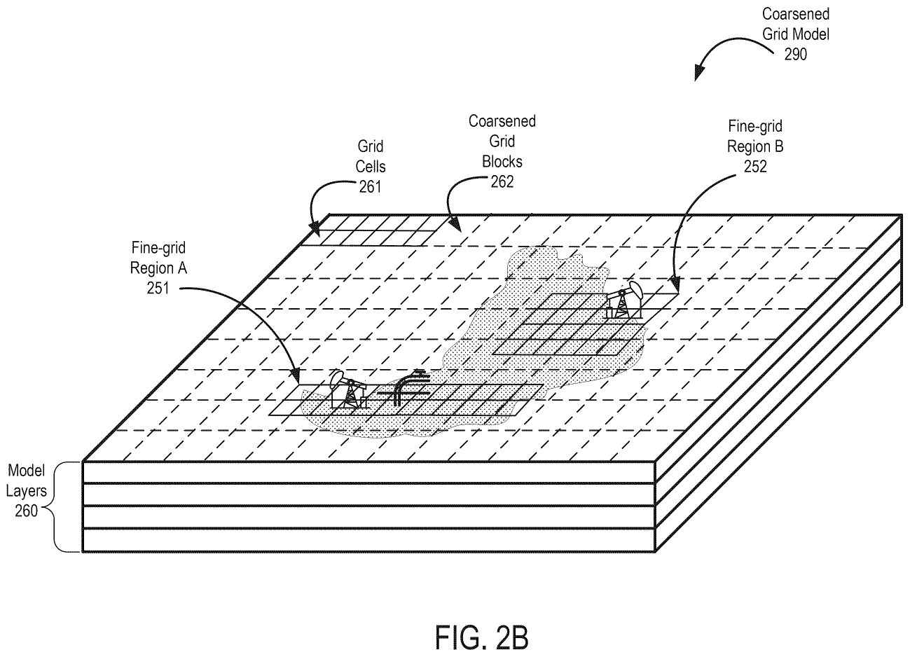

Turning to FIG. 2A, FIG. 2A shows a schematic diagram in accordance with one or more embodiments. As illustrated in FIG. 2A, FIG. 2A shows a geological region (200) that may include one or more reservoir regions (e.g., reservoir region (230)) with various production wells (e.g., production well A (211), production well (212)). For example, a production well may be similar to the well system (106) described above in FIG. 1 and the accompanying description. Likewise, a reservoir region may also include one or more injection wells (e.g., injection well C (216)) that include functionality for enhancing production by one or more neighboring production wells. As shown in FIG. 2A, wells may be disposed in the reservoir region (230) above various subsurface layers (e.g., subsurface layer A (241), subsurface layer B (242)), which may include hydrocarbon deposits.

Turning to FIG. 2B, FIG. 2B shows a schematic diagram in accordance with one or more embodiments. As illustrated in FIG. 2B, FIG. 2B shows a coarsened grid model (290) that corresponds to the geological region (200) from FIG. 2A. More specifically, the coarsened grid model (290) includes grid cells (261) that may refer to an original cell of a grid model as well as coarsened grid blocks (262) that may refer to an amalgamation of original cells of the grid model. For example, a grid cell may be the case of a 1×1 block, where coarsened grid blocks may be of sizes 2×2, 4×4, 8×8, etc. Both the grid cells (261) and the coarsened grid blocks (262) may correspond to columns for multiple model layers (260) within the coarsened grid model (290).

Prior to performing a simulation, local grid refinement and coarsening (LGR) may be used to increase or decrease grid resolutions in various regions of a grid model. For example, various reservoir properties, e.g., permeability, porosity, or saturations, may correspond to discrete values that are associated with a particular grid cell or coarsened grid block. However, by using discrete values to represent a portion of a geological region, a discretization error may occur in a reservoir simulation. Thus, various fine-grid regions may reduce discretization errors as the numerical approximation of a finer grid is closer to the exact solution, however through a higher computational cost. As shown in FIG. 2B, for example, the coarsened grid model (290) may include various fine-grid regions (i.e., fine-grid region A (251), fine-grid region B (252)), that are surrounded by coarsened block regions. Likewise, the original grid model without any coarsening may be referred to as a fine-grid model.

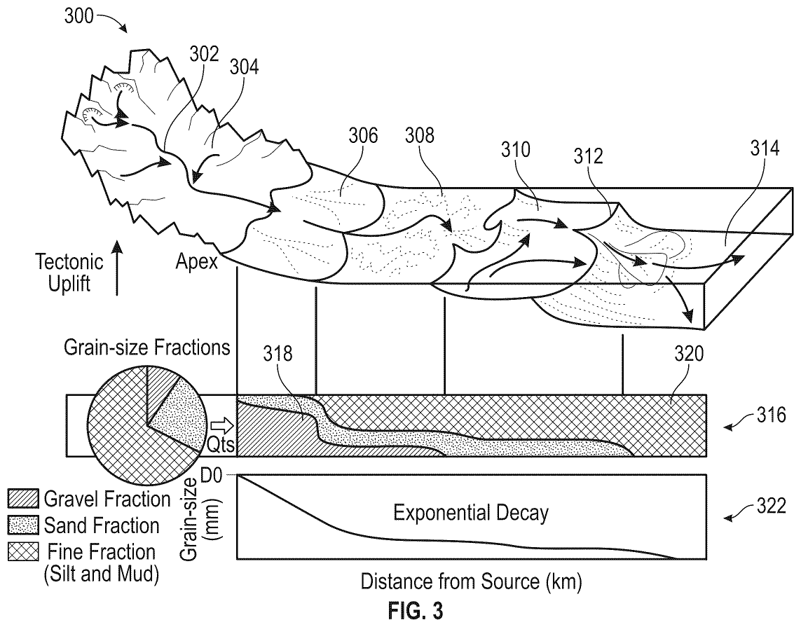

Turning to FIG. 3, FIG. 3 illustrates a sedimentary system showing a progression of different grain types and grain sizes in a geologic region (300) in accordance with one or more embodiments. In particular, a sedimentary system may describe a sedimentary pathway from a sedimentary source location to a final sediment deposition. For geological process simulations, sedimentary pathway data may form input parameters to comprehensive numerical modeling of sedimentary systems, e.g., forward depositional-diagenetic modelling. In FIG. 3, the geologic region (300) includes a sedimentary pathway (302) that includes a variety of rock grains of various sizes, shapes, and types. The sedimentary pathway (302) starts at a catchment (304) and flows through a gravel alluvial fan (306), an alluvial plain (308), a coastal fence (310), and a shelf-slope break (312) before settling in a deep marine basin (314). Within this sedimentary pathway (302), different types of grains may be categorized according to different geological facies such as sand or fine-grain deposits. As the sedimentary pathway (302) passes through various zones, different-sized grains may get deposited along the sedimentary pathway and exit the load of sediment. In particular, the larger, heavier, and coarser sediment particles may depart from a sediment flow earlier than the smaller, lighter, finer sediment particles, such as sand. The sedimentary pathway (302) may have a sedimentary source that originates sedimentary particles for deposition along the sedimentary pathway (302).

Further, cross-section (316) illustrates an example division between gravel (318) and sand (320) as the sedimentary pathway (302) continues away from a sedimentary source. For example, the gravel alluvial fan (306) may include a greater total number of gravel-sized grains than the deep marine basin (314). In some cases, the average grain size may decrease according to an exponential-decay equation. In other words, the average grain size may exponentially decrease as the sedimentary pathway (302) continues away from the sedimentary source. In these instances, the exponential decay of the average grain size may be used to determine a sedimentary source location within the geological region (300).

Keeping with sedimentary pathways, a sedimentary source location may be determined using various techniques in accordance with one or more embodiments. For example, a grain size distribution of a geological region may be divided into a Cartesian grid, where each grid point may be a potential sedimentary source location. The grain size distribution may be based on geological data acquired from various well sources and analyzed accordingly. The geological data may include cuttings, core samples, well log data, and any other geological data representative of a formation or stratigraphic layer. As such, a grain size dataset may be generated that illustrates an average grain size for cells within a geological region's grid.

While FIGS. 1, 2A, 2B, and 3 show various configurations of components, other configurations may be used without departing from the scope of the disclosure. For example, various components in FIGS. 1, 2A, 2B, and 3 may be combined to create a single component. As another example, the functionality performed by a single component may be performed by two or more components.

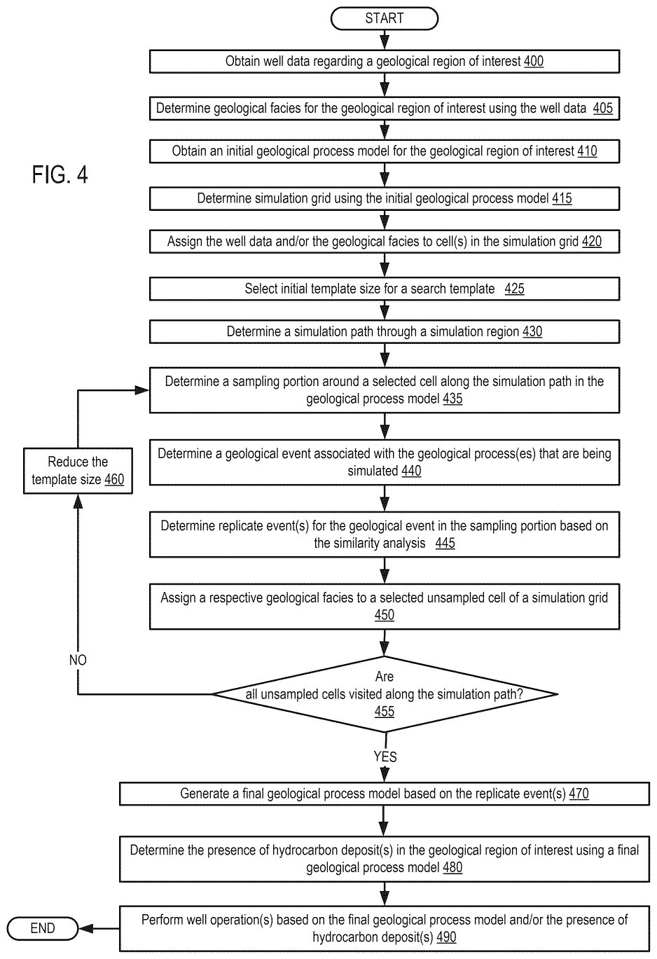

Turning to FIG. 4, FIG. 4 shows a flowchart in accordance with one or more embodiments. Specifically, FIG. 4 describes a general method for generating one or more geological process models using an adjustable search template. One or more blocks in FIG. 4 may be performed by one or more components (e.g., reservoir simulator (160)) as described in FIGS. 1, 2A, 2B, and 3. While the various blocks in FIG. 4 are presented and described sequentially, one of ordinary skill in the art will appreciate that some or all of the blocks may be executed in different orders, may be combined or omitted, and some or all of the blocks may be executed in parallel. Furthermore, the blocks may be performed actively or passively.

In Block 400, well data are obtained regarding a geological region of interest in accordance with one or more embodiments. More specifically, well data may be acquired at one or more wells in a geological region. Examples of well data may include well logs, core sample data, and cutting data. For more information on well data, see FIG. 1 above and the accompanying description. In some embodiments, a reservoir simulator preprocesses well data in order to determine geological input data for generating a geological process model, running a geological simulation, or providing a conditioning process. A geological region of interest may be a portion of a geological area or volume desired or selected for further analysis, e.g., for simulating one or more depositional or diagenetic processes. Likewise, a geological region of interest may include one or more reservoir regions selected for running simulations. For example, the geological region of interest may be similar to geological region (200) or reservoir region (230) described above in FIG. 2A and the accompanying description.

In Block 405, one or more geological facies are determined for a geological region of interest using well data in accordance with one or more embodiments. More specifically, geological facies may describe various geological properties in such a way as to distinguish different bodies of rock into mappable units. Example geological properties may include specific physical characteristics, chemical composition types, formation types, or various other geological attributes. In some embodiments, geological facies include one or more rock types, such as shales, sandstones, and carbonates.

In Block 410, an initial geological process model is obtained for a geological region of interest in accordance with one or more embodiments. A geological process model may be a grid model where various cells are assigned one or more geological property values. For example, a geological process model may be similar to a fine-grid model and/or a coarsened-grid model described above in FIG. 2B and the accompanying description. Different cells and/or coarsened block may be associated with acquired well data and/or simulated data in the initial model.

In some embodiments, an initial geological process model is generated by performing one or more geological simulations based on one or more geological processes. Following a process-based geological modeling, geological simulation results may be represented as geological facies in a 3D grid (e.g., similar to FIG. 2B above). Thus, a portion of the initial geological process model may be used to obtain one or more training images for a conditioning or calibration procedure. The grid cell size in an initial geological process model may be defined based on spatial variability of various heterogeneous features in a respective training image. As such, various significant geological features can be represented in an initial grided model or one or more training images.

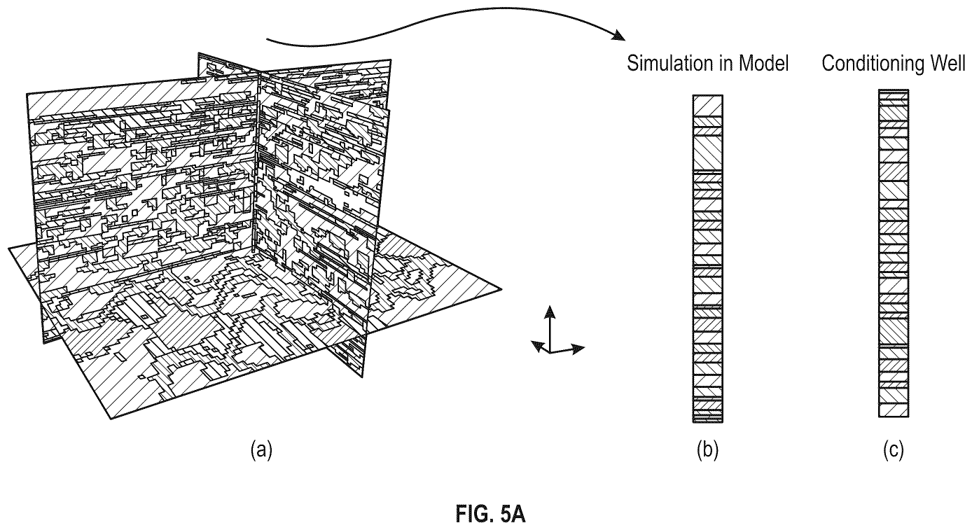

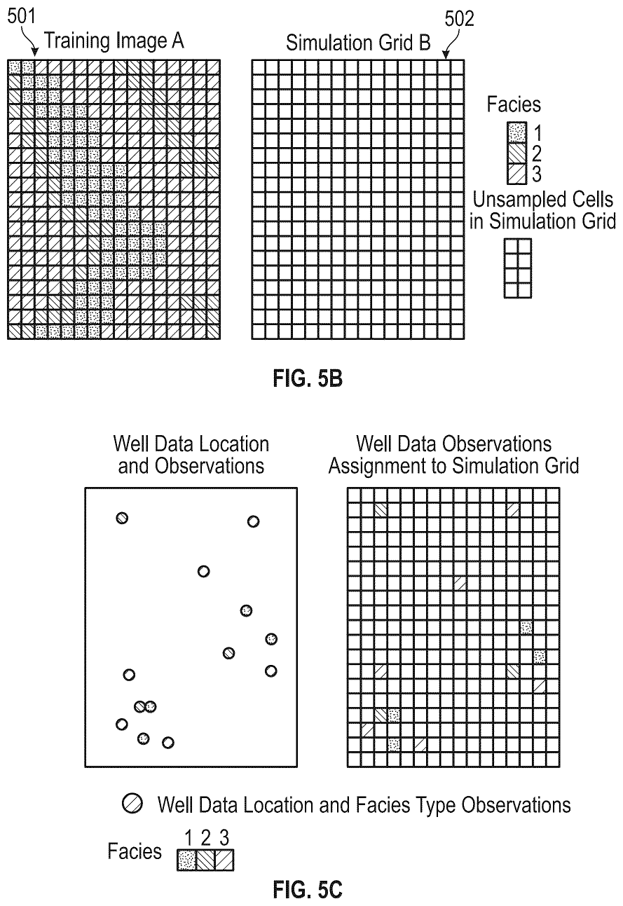

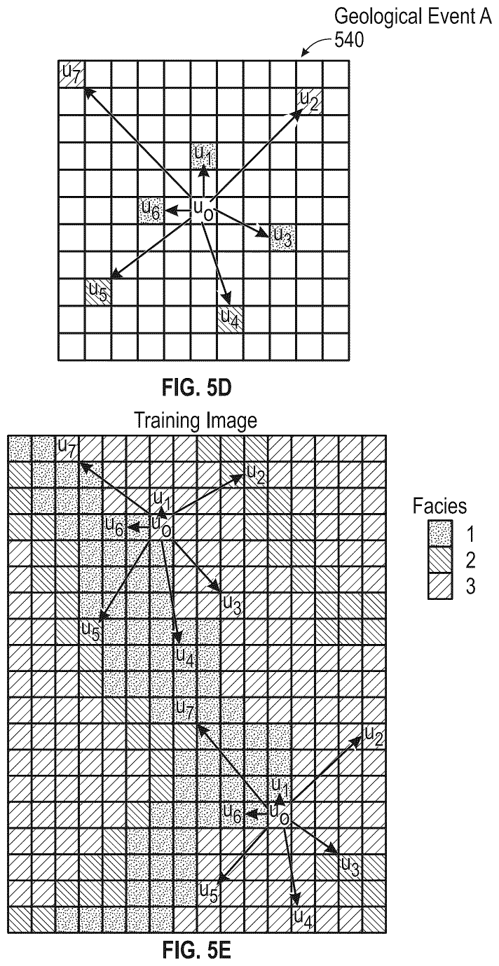

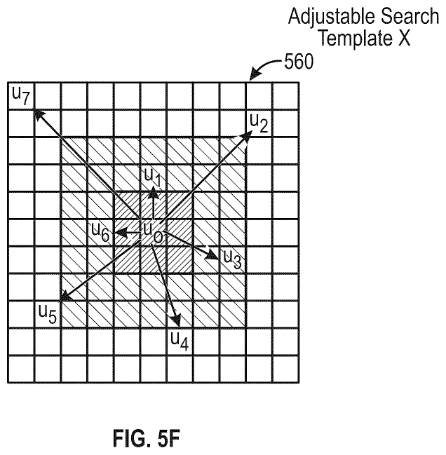

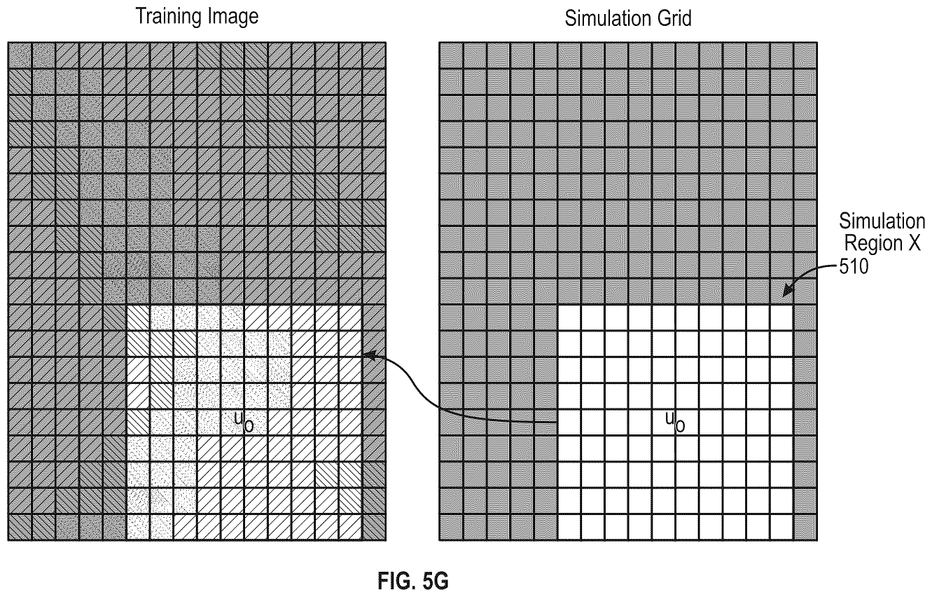

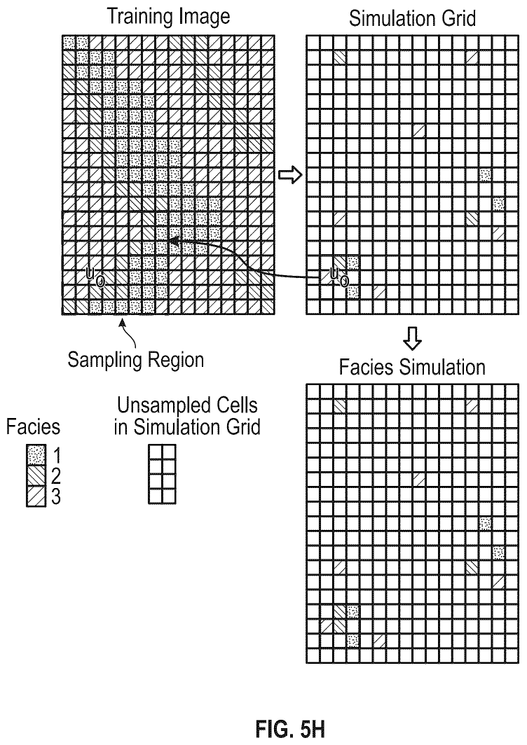

Turning to FIG. 5A, FIG. 5A shows an example of a geological process model in accordance with one or more embodiments. In particular, FIG. 5A shows various well depths in a simulated 3D depositional model in comparison to acquired well data from the field. FIG. 5A (a) illustrates the 3D process-based depositional model, while FIG. 5A (b) shows various geological facies types along a corresponding well based on running geological process simulations. Likewise, FIG. 5A (c) shows various geological facies based on analyzing hard well data. As shown in FIG. 5A, the simulated facies data and the acquired facies data are not necessarily well honored in the resulting depositional model. In some embodiments, an initial geological process model, such as FIG. 5A, may be conditioning or calibrating to acquired data (e.g., acquired well data).

Returning to FIG. 4, in Block 415, a simulation grid is determined using an initial geological process model in accordance with one or more embodiments. In some embodiments, for example, a simulation grid is the same as a training image from an initial geological process model. An illustration of an example simulation grid is shown in FIG. 5B. In FIG. 5B, a training image from an initial geological process model is shown with three types of geological facies using different shadings. Additionally, various cells in the simulation grid may be empty prior to performing a conditioning or calibration process.

In Block 420, well data and/or one or more geological facies are assigned to one or more cells in a simulation grid in accordance with one or more embodiments. In some embodiments, acquired well data is assigned to various model grid cells in the simulation region to simulate a geological event or determine replicate events of the geological event. Afterwards, geological properties may be assigned to empty cells one after another. For example, acquired well data may be scattered throughout a geological region (e.g., a reservoir field) such that a specific well dataset may be assigned to its closest respective simulation grid cells, as shown in FIG. 5C.

In Block 425, an initial template size is selected for a search template in accordance with one or more embodiments. During a simulation of cells in the simulation grid, simulated data and empty cells are analyzed using a search template. A search template may be a predetermined area in the simulation grid that is used to search a training image or other portion of a geological process model. In a conditioning process, the search template may have a default or selected size that may be rescaled through the conditioning process. A larger search template may include more analyzed data (e.g., acquired well data or previously simulated data) that may better capture long range heterogeneity in a sampling region. On the other hand, a smaller template size may have better performance for determining replicate events of a searched geological event in the training image. As such, the initial template size may be used for the initial search of a training image for replicate events along a simulation path.

In Block 430, a simulation path is determined through a simulation region in accordance with one or more embodiments. The simulation path may be a random path, for example, that is used to implement a stochastic simulation method based on the multiscale regionalized direct sampling scheme. Using a selected search template, a portion of a simulation grid may be subsequently selected as the simulation region for performing the geological simulation or conditioning procedure. Moreover, by sampling from a simulation region around each cell instead of an entire training image may be used to reproduce spatial trends of a simulated geological process model. Using this simulation path, a reservoir simulator may honor acquired well data in the simulation region while also reproducing spatial geological features at various scales.

In some embodiments, for example, a geological simulation based on a simulation path produces various geometric patterns and trends using process-based geological modeling. FIG. 5G shows an example of a simulation region X (510) in a simulation grid B (502), where the simulation region X (510) analyzes the training image A (501). To account for an areal trend or non-stationarity of a geological process model, a search method may move along a simulation path to determine replicate events in a certain simulation region around a primary cell being simulated. FIG. 5G shows an example of sampling region around a cell u₀.

In Block 435, a sampling portion around a selected cell along a simulation path is determined in a geological process model in accordance with one or more embodiments.

In Block 440, a geological event is determined that is associated with one or more geological processes that are being simulated in accordance with one or more embodiments. A geological event may be a data event that corresponds to a set of data (e.g., initial acquired well data and previously simulated cells) in a neighborhood of a simulation region defined by a search template of a predetermined cell that is undergoing analysis. However, the geological facies associated with the geological event may be known for the primary cell that is the basis for the geological event. In some embodiments, for example, a geological event may be identified using acquired well data.

Turning to FIG. 5D, FIG. 5D shows an example geological event A (540) being analyzed within a simulation region in accordance with one or more embodiments. In FIG. 5D, a categorical geological property z(u) may correspond to K possible states 1, 2 . . . K. A geological event dₙ of cell size n centered at an unsampled location u₀ may be constituted by a data geometry defined by the n data locations (i.e., {u_{α}, α=1, . . . , n}) and the categorical geological property determined at these n data locations (i.e., {z(u_{α}), α=1, . . . , n}). As such, FIG. 5D illustrates a geological event within a template of 11 by 11 cells for the unsampled location u₀. The data geometry of the geological event may be defined by seven data locations for the following cells: u₁, u₂, u₃, u₄, u₅, u₆, and u₇. Moreover, three types of geological facies are associated with this geological event and labeled as ‘1’, ‘2’, and ‘3’ for various cells in the simulation region. More specifically, an example geological event may be expressed with various labeled geological facies using the following equation:

$${d}_{7} ( {u}_{0} ) = \{ z ( {u}_{1} \} = 1 , z \{ {u}_{2} ) = 3 , z ( {u}_{3} \} = 1 , z ( {u}_{4} ) = 2 , z ( {u}_{5} \} = 2 , z \{ {u}_{6} ) = 1 , z ( {u}_{7} ) = 3 \} \qquad Equation 1$$

In Block 445, one or more replicate events are determined for a geological event in a sampling portion based on a similarity analysis in accordance with one or more embodiments. A replicate event may be a data event based on neighboring cells around a cell of interest that is similar to an identified geological event. After sampling a geological event in a training image, replicate events are searched within a simulation region of the training image. By sampling an alleged replicate event, a geological property is assigned at the center of the replicate to the cell being simulated. To determine whether an alleged replicant event corresponds to a particular geological event, one or more similarity metrics are used to compare the geological event and the alleged replicate event. For example, similarity between two geological events

$$d ( {u}_{0}^{x} ) and d ( {u}_{0}^{y} )$$

may determined using the following equations:

$$s [ d ( {u}_{0}^{x} ) , d ( {u}_{0}^{y} ) ] = \frac{1}{n} {\sum }_{i = 1}^{n} {a}_{i} \qquad Equation 2$$

$$z ( {u}_{i}^{x} ) , z ( {u}_{i}^{y} ) ∈ [ 1 , 2 , … K ] \qquad Equation 3$$

$${a}_{i} = \{ \begin{matrix}0 & if z ( {u}_{i}^{x} ) = z ( {u}_{i}^{y} ) \\ 1 & if z ( {u}_{i}^{x} ) \neq z ( {u}_{i}^{y} )\end{matrix} \qquad Equation 4$$

where i=1, 2, . . . , n, s corresponds to a predetermined similarity metric function, d corresponds to a geological event, and ai corresponds a similarity metric threshold.

Turning to FIG. 5E, FIG. 5E shows two geological events,

$$d ( {u}_{0}^{x} ) and d ( {u}_{0}^{y} ) ,$$

at different cell locations in a training image. The geological events in FIG. 5E may be expressed using the following equations:

$$d ( {u}_{0}^{x} ) = \{ z ( {u}_{1} ) = 1 , z ( {u}_{2} ) = 3 , z ( {u}_{3} ) = 2 , z ( {u}_{4} ) = 3 , z ( {u}_{5} ) = 1 , z ( {u}_{6} ) = 1 , z ( {u}_{7} ) = 1 \} \qquad Equation 5$$

$$d ( {u}_{0}^{y} ) = \{ z ( {u}_{1} ) = 3 , z ( {u}_{2} ) = 2 , z ( {u}_{3} ) = 3 , z ( {u}_{4} ) = 1 , z ( {u}_{5} ) = 2 , z ( {u}_{6} ) = 1 , z ( {u}_{7} ) = 3 \} \qquad Equation 6$$

Based on a similarity analysis between geological events,

$$d ( {u}_{0}^{x} ) and d ( {u}_{0}^{y} ) ,$$

in FIG. 5E, the similarity is measured by the following equation:

$$s [ d ( {u}_{0}^{x} ) , d ( {u}_{0}^{y} ) ] = \frac{1}{7} ( 1 + 1 + 1 + 1 + 1 + 0 + 1 ) = \frac{6}{7} ≅ 0.8571 \qquad Equation 7$$

where the determined value identifies the geological events.

$$d ( {u}_{0}^{x} ) and d ( {u}_{0}^{y} ) ,$$

being quite different. The similarity metric s may use a value range of [0, 1]. When the calculated similarity s is close to 0, two geological events are more similar. When the metric's distance is closer to 1, the two geological events are more different. As such, a stronger likelihood exists that geological facies at

$${u}_{0}^{x} and {u}_{0}^{y}$$

in FIG. 5E are also different based on the similarity metric.

Returning to FIG. 4, in Block 450, a respective geological facies is assigned to a selected unsampled cell of a simulation grid in accordance with one or more embodiments. In some embodiments, the similarity analysis is the similarity analysis described above with respect to Block 445. After a replicate event is found in a simulation region, the geological facies at its center is directly assigned to the corresponding cell of the simulation grid. If no such replicate events are found within the simulation region, the cell at this location may remain empty temperately until assigned a geological facies value at a later stage in the geological simulation with an adjusted search template (e.g., such as a reduced search template).

Turning to FIG. 5H, FIG. 5H illustrates one step of a facies assignment for an unassigned cell in a simulation region. Using regionalized direct sampling, a replicate event is shown being matched exactly to a specific geological event found in the right top corner of the simulation region. As described above, this matching may be performed using one or more similarity metrics. Although an exact match may not be required to identify a replicate event, the degree of match between the geological event and the proposed replicate event in a training image may meet a particular threshold or other predetermined criterion.

Returning to FIG. 4, in Block 455, a determination is made whether all unsampled cells are visited along a simulation path in accordance with one or more embodiments. In particular, a reservoir simulator may use one or more simulation paths to traverse multiple sampling regions until an entire geological process model has been traversed. For each unsampled cell of the simulation grid, a reservoir simulator may analyze a corresponding cell from a training image to determine a geological facies for a selected unsampled cell. For example, an initial geological process model may be fully calibrated after completing iterative simulations over one or more training images. After a conditioning process is completed on a geological process model, another conditioning process may also be performed, such as when new well data is acquired for a corresponding geological region. If any cells remain unassigned, the process may proceed to Block 460. Otherwise, the process may proceed to Block 470.

In some embodiments, for example, a reservoir simulator selects different cells along a simulation path in an iterative manner until all cells are assigned a corresponding geological facies.

In Block 460, a template size is reduced in accordance with one or more embodiments. For example, a conditioning process may start with a large search template to capture large scale geological features in a training image. The size of the search template may be reduced by the reservoir simulator progressively to represent smaller scale features. In some embodiments, the template size is changed level by level or even cell by cell from its edges to the center of the search template. In some embodiments, for example, search templates are nested such that template sizes shrink progressively throughout a conditioning process. Template sizes may also be automatically selected by a reservoir simulator or other computer device based on a desired computing time for a conditioning process. For example, a predetermined number of template sizes, such as three total sizes, may be selected accordingly. FIG. 5F illustrates one or more embodiments that include various multiscale search templates. In FIG. 5F, an initial size of an adjustable search template X (560) is 11 by 11 grid cells, while a second size of an adjusted search template is 7 by 7 grid cells. Finally, the last size of the adjustable search template X (560) corresponds to a 3 by 3 grid of cells.

In Block 470, a final geological process model is generated based on one or more replace events in accordance with one or more embodiments. For example, various cells in an input geological process model may be updated based on finding similar replicate events to selected geological events. This conditioning process may thereby preserve the underlying geological processes in a geological region, such as to make the final model more reliable for reservoir forecasting.

In Block 480, a presence of hydrocarbon deposits is determined in a geological region of interest using a final geological process model in accordance with one or more embodiments. For example, a final geological process model may be used to determine the locations of one or more hydrocarbon deposits in one or more reservoir regions. Likewise, the final geological process model may be used to predict hydrocarbon accumulations, such as for managing injection operations, production operations, well intervention operations, and the drilling of various exploratory wells.

In Block 490, one or more well operations are performed based on a final geological process model and/or a presence of hydrocarbon deposits in accordance with one or more embodiments. In some embodiments, for example, a drilling system performs a drilling operation using a well path based on the final geological process model. Likewise, a reservoir simulator or other computer device may transmit a command to a control system at a production well to adjust one or more wellhead parameters based on the final geological process model. In some embodiments, one or more new well locations are selected to develop a reservoir to produce hydrocarbon production based on the final geological process model.

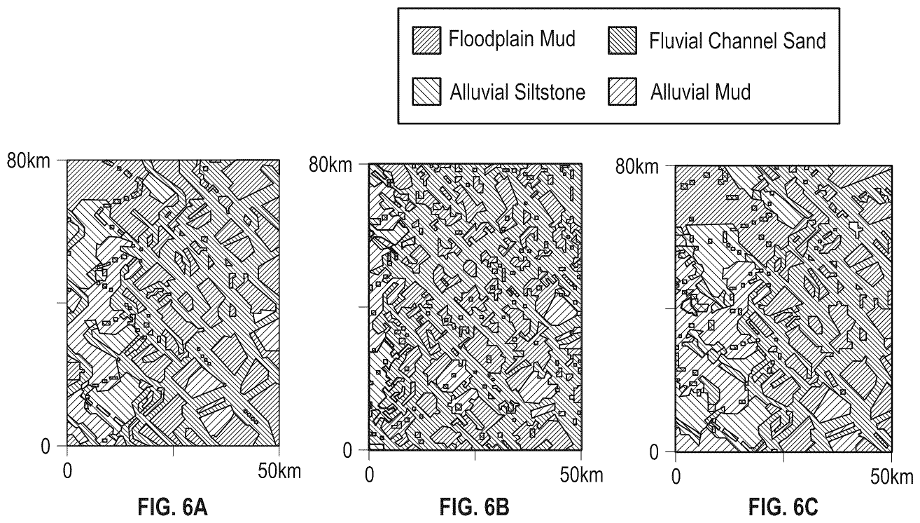

Turning to FIGS. 6A, 6B, and 6C, FIGS. 6A-6C illustrate several examples of conditioning geological process models to well data. A training image is used that is a geological object-based model representing a meandering channelized depositional system as shown in FIG. 6A. There are four geological facies in the illustrated model: (1) floodplain mud, (2) fluvial channel sand, (3) alluvial siltstone, and (4) alluvial mud. The facies distribution in the model presents a trend with more alluvial siltstone and alluvial mud on the left of the depositional system but with more fluvial channel sand and floodplain mud on its right. First, a realization is determined by using a regionalized direct sampling method with a unique search template as shown in FIG. 6B. Then, a realization is determined by using the regionalized direct sampling method with three search templates with different scales as shown in FIG. 6C. The results of the different conditioning techniques shows clearly that the multiscale regionalized direct sampling method can effectively reproduce the geological patterns and trend of the initial geological process model.

Embodiments may be implemented on a computer system. FIG. 7 is a block diagram of a computer system (702) used to provide computational functionalities associated with described algorithms, methods, functions, processes, flows, and procedures as described in the instant disclosure, according to an implementation. The illustrated computer (702) is intended to encompass any computing device such as a high performance computing (HPC) device, server, desktop computer, laptop/notebook computer, wireless data port, smart phone, personal data assistant (PDA), tablet computing device, one or more computer processors within these devices, or any other suitable processing device, including both physical or virtual instances (or both) of the computing device. Additionally, the computer (702) may include a computer that includes an input device, such as a keypad, keyboard, touch screen, or other device that can accept user information, and an output device that conveys information associated with the operation of the computer (702), including digital data, visual, or audio information (or a combination of information), or a GUI.

The computer (702) can serve in a role as a client, network component, a server, a database or other persistency, or any other component (or a combination of roles) of a computer system for performing the subject matter described in the instant disclosure. The illustrated computer (702) is communicably coupled with a network (730). In some implementations, one or more components of the computer (702) may be configured to operate within environments, including cloud-computing-based, local, global, or other environment (or a combination of environments).

At a high level, the computer (702) is an electronic computing device operable to receive, transmit, process, store, or manage data and information associated with the described subject matter. According to some implementations, the computer (702) may also include or be communicably coupled with an application server, e-mail server, web server, caching server, streaming data server, business intelligence (BI) server, or other server (or a combination of servers).

The computer (702) can receive requests over network (730) from a client application (for example, executing on another computer (702)) and responding to the received requests by processing the said requests in an appropriate software application. In addition, requests may also be sent to the computer (702) from internal users (for example, from a command console or by other appropriate access method), external or third-parties, other automated applications, as well as any other appropriate entities, individuals, systems, or computers.

Each of the components of the computer (702) can communicate using a system bus (703). In some implementations, any or all of the components of the computer (702), both hardware or software (or a combination of hardware and software), may interface with each other or the interface (704) (or a combination of both) over the system bus (703) using an application programming interface (API) (712) or a service layer (713) (or a combination of the API (712) and service layer (713). The API (712) may include specifications for routines, data structures, and object classes. The API (712) may be either computer-language independent or dependent and refer to a complete interface, a single function, or even a set of APIs. The service layer (713) provides software services to the computer (702) or other components (whether or not illustrated) that are communicably coupled to the computer (702). The functionality of the computer (702) may be accessible for all service consumers using this service layer. Software services, such as those provided by the service layer (713), provide reusable, defined business functionalities through a defined interface. For example, the interface may be software written in JAVA, C++, or other suitable language providing data in extensible markup language (XML) format or other suitable format. While illustrated as an integrated component of the computer (702), alternative implementations may illustrate the API (712) or the service layer (713) as stand-alone components in relation to other components of the computer (702) or other components (whether or not illustrated) that are communicably coupled to the computer (702). Moreover, any or all parts of the API (712) or the service layer (713) may be implemented as child or sub-modules of another software module, enterprise application, or hardware module without departing from the scope of this disclosure.

The computer (702) includes an interface (704). Although illustrated as a single interface (704) in FIG. 7, two or more interfaces (704) may be used according to particular needs, desires, or particular implementations of the computer (702). The interface (704) is used by the computer (702) for communicating with other systems in a distributed environment that are connected to the network (730). Generally, the interface (704 includes logic encoded in software or hardware (or a combination of software and hardware) and operable to communicate with the network (730). More specifically, the interface (704) may include software supporting one or more communication protocols associated with communications such that the network (730) or interface's hardware is operable to communicate physical signals within and outside of the illustrated computer (702).

The computer (702) includes at least one computer processor (705). Although illustrated as a single processor (705) in FIG. 7, two or more computer processors may be used according to particular needs, desires, or particular implementations of the computer (702). Generally, the computer processor (705) executes instructions and manipulates data to perform the operations of the computer (702) and any algorithms, methods, functions, processes, flows, and procedures as described in the instant disclosure.

The computer (702) also includes a memory (706) that holds data for the computer (702) or other components (or a combination of both) that can be connected to the network (730). For example, memory (706) can be a database storing data consistent with this disclosure. Although illustrated as a single memory (706) in FIG. 7, two or more memories may be used according to particular needs, desires, or particular implementations of the computer (702) and the described functionality. While memory (706) is illustrated as an integral component of the computer (702), in alternative implementations, memory (706) can be external to the computer (702).

The application (707) is an algorithmic software engine providing functionality according to particular needs, desires, or particular implementations of the computer (702), particularly with respect to functionality described in this disclosure. For example, application (707) can serve as one or more components, modules, applications, etc. Further, although illustrated as a single application (707), the application (707) may be implemented as multiple applications (707) on the computer (702). In addition, although illustrated as integral to the computer (702), in alternative implementations, the application (707) can be external to the computer (702).

There may be any number of computers (702) associated with, or external to, a computer system containing computer (702), each computer (702) communicating over network (730). Further, the term “client,” “user,” and other appropriate terminology may be used interchangeably as appropriate without departing from the scope of this disclosure. Moreover, this disclosure contemplates that many users may use one computer (702), or that one user may use multiple computers (702).

In some embodiments, the computer (702) is implemented as part of a cloud computing system. For example, a cloud computing system may include one or more remote servers along with various other cloud components, such as cloud storage units and edge servers. In particular, a cloud computing system may perform one or more computing operations without direct active management by a user device or local computer system. As such, a cloud computing system may have different functions distributed over multiple locations from a central server, which may be performed using one or more Internet connections. More specifically, cloud computing system may operate according to one or more service models, such as infrastructure as a service (IaaS), platform as a service (PaaS), software as a service (SaaS), mobile “backend” as a service (MBaaS), serverless computing, and/or function as a service (FaaS).

Although only a few example embodiments have been described in detail above, those skilled in the art will readily appreciate that many modifications are possible in the example embodiments without materially departing from this invention. Accordingly, all such modifications are intended to be included within the scope of this disclosure as defined in the following claims.

What is claimed:

1. A method, comprising:
obtaining well data regarding a geological region of interest;
obtaining a first geological process model for the geological region of interest;
determining, by a computer processor, a simulation region of the first geological process model based on a first template size and a simulation grid;
determining, by the computer processor, a simulation path through the simulation region;
determining, by the computer processor, a first geological event associated with a predetermined geological facies based on the well data;
determining, by the computer processor, a first replicate event based on the first geological event, a similarity analysis, and using the simulation path; and
assigning, by the computer processor, the predetermined geological facies to a cell location of the first replicate event in the simulation region in response to determining that the first replicate event satisfies a predetermined criterion; and
updating, by the computer processor, the first geological process model to produce an updated geological process model,
wherein the updated geological process model comprises the predetermined geological facies in the cell location of the updated geological process model.

2. The method of claim 1, further comprising:
obtaining a training image based on the first geological process model; and
determining a simulation grid based on the training image,
wherein the simulation region corresponds to a portion of the simulation grid that matches the first template size.

3. The method of claim 1, further comprising:
determining a second geological event at a first cell position in the first geological process model;
determining a second replicate event at a second cell position in the simulation region along the simulation path;
performing a comparison between the second geological event and the second replicate event using a similarity metric;
determining whether the second geological event and the second replicate event satisfy a similarity threshold based on the comparison; and
determining, in response to the comparison satisfying the similarity threshold, that the second replicate event corresponds to the second geological event.

4. The method of claim 1, further comprising:
determining a second template size for a second simulation path;
determining a first plurality of replicate events in a second simulation region using the second template size;
adjusting the second template size to produce a third template size, wherein the third template size is smaller than the second template size; and
determining a second plurality of replicate events in the second simulation region using the third template size.

5. The method of claim 1,
wherein the predetermined geological facies is selected from a group consisting of a floodplain mud, a fluvial channel sand, an alluvial siltstone, and an alluvial mud.

6. The method of claim 1, further comprising:
determining a presence of hydrocarbons in the geological region of interest using the updated geological process model.

7. The method of claim 1, further comprising:
adjusting, using a control system coupled to a reservoir simulator, one or more well operations at a predetermined well based on the updated geological process model,
wherein the updated geological process model is updated by the reservoir simulator.

8. The method of claim 1,
wherein a portion of the well data is based on a plurality of elemental logs for one or more wellbores, and
wherein the plurality of elemental logs are determined using a plurality of cuttings and an X-ray fluorescence (XRF) spectrometer.

9. The method of claim 1, further comprising:
transmitting a command to a control system based on the updated geological process model,
wherein the control system is coupled to a wellhead assembly, and
wherein the command adjusts one or more production parameters of the wellhead assembly.

10. A system, comprising:
a drilling system comprising a plurality of sensors and a drill string comprising a drill bit, wherein the drilling system is coupled to a wellbore; and
a reservoir simulator coupled to the drilling system, wherein the reservoir simulator comprises a computer processor, the reservoir simulator is configured to perform a method comprising:
obtaining well data regarding a geological region of interest,
obtaining a first geological process model for the geological region of interest,
determining a simulation region of the first geological process model based on a first template size and a simulation grid,
determining a simulation path through the simulation region,
determining a first geological event associated with a predetermined geological facies based on the well data,
determining a first replicate event based on the first geological event, a similarity analysis, and using the simulation path, and
assigning the predetermined geological facies to a cell location of the first replicate event in the simulation region in response to determining that the first replicate event satisfies a predetermined criterion, and
updating the first geological process model to produce an updated geological process model,
wherein the updated geological process model comprises the predetermined geological facies in the cell location of the updated geological process model, and
wherein the drilling system is configured to perform a drilling operation for a well path based on the updated geological process model.

11. The system of claim 10, wherein the method further comprises:
obtaining a training image based on the first geological process model; and
determining a simulation grid based on the training image,
wherein the simulation region corresponds to a portion of the simulation grid that matches the first template size.

12. The system of claim 10, wherein the method further comprises:
determining a second geological event at a first cell position in the first geological process model;
determining a second replicate event at a second cell position in the simulation region along the simulation path;
performing a comparison between the second geological event and the second replicate event using a similarity metric;
determining whether the second geological event and the second replicate event satisfy a similarity threshold based on the comparison; and
determining, in response to the comparison satisfying the similarity threshold, that the second replicate event corresponds to the second geological event.

13. The system of claim 10, wherein the method further comprises:
determining a second template size for a second simulation path;
determining a first plurality of replicate events in a second simulation region using the second template size;
adjusting the second template size to produce a third template size, wherein the third template size is smaller than the second template size; and
determining a second plurality of replicate events in the second simulation region using the third template size.

14. The system of claim 10,
wherein the predetermined geological facies is selected from a group consisting of a floodplain mud, a fluvial channel sand, an alluvial siltstone, and an alluvial mud.

15. The system of claim 10, wherein the method further comprises:
determining a presence of hydrocarbons in the geological region of interest using the updated geological process model.

16. The system of claim 10,
wherein a portion of the well data is based on a plurality of elemental logs for one or more wellbores, and
wherein the plurality of elemental logs are determined using a plurality of cuttings and an X-ray fluorescence (XRF) spectrometer.

17. The system of claim 10, further comprising:
a coring system comprising a coring tool,
wherein one or more core samples are acquired from the wellbore using the coring tool, and
wherein a portion of the well data is based on core sample data using the one or more core samples.

18. The system of claim 10, further comprising:
a logging system comprising a logging tool,
wherein one or more well logs are acquired from the wellbore using the logging tool, and
wherein a portion of the well data is based on well log data using the one or more well logs.
